(19) United States
(12) Patent Application Publication
(10) Pub. No.: US 2024/0405038 A1
(43) Pub. Date: Dec. 5, 2024

(54) IMAGING DEVICE

(71) Applicant: Panasonic Intellectual Property Management Co., Ltd., Osaka (JP)

(72) Inventor: MASAMI FUNABASHI, Osaka (JP)

(21) Appl. No.: 18/796,257

(22) Filed: Aug. 6, 2024

Related U.S. Application Data
(63) Continuation of application No. PCT/JP2022/047745, filed on Dec. 23, 2022.

(30) Foreign Application Priority Data
Mar. 3, 2022 (JP) 2022-032956

(51) Int. Cl. H01L 27/146; H04N 25/65; H04N 25/709; H04N 25/77

(52) U.S. Cl. CPC H01L 27/14612; H04N 25/65; H04N 25/709; H04N 25/77

(57) ABSTRACT

An imaging device includes a first pixel and a second pixel each provided with a photoelectric converter that converts light into electric charges and a first transistor connected to the photoelectric converter, first wiring connected to one of a source and a drain of the first transistor of the first pixel, second wiring connected to one of a source and a drain of the first transistor of the second pixel, a first voltage line to which a first voltage is applied, and a first amplification circuit that is connected to the first voltage line, amplifies the first voltage, and outputs the amplified first voltage to the first wiring and the second wiring.

### BACKGROUND

### 1. Technical Field

The present disclosure relates to an imaging device.

### 2. Description of the Related Art

In recent years, imaging devices have been widely used in various product fields including video cameras, digital still cameras, monitoring cameras, in-vehicle cameras, and the like. Charge coupled device (CCD) type solid-state imaging elements or complementary metal oxide semiconductor (CMOS) type solid-state imaging elements are used as the imaging devices (see Japanese Unexamined Patent Application Publication No. 2016-127593 and International Publication No. WO 2020/079884, for example). Above all, the CMOS type solid-state imaging elements are becoming the mainstream. The CMOS type solid-state imaging elements can be manufactured by using a general-purpose CMOS process so that the imaging elements can be stably supplied while using the existing facilities. In the meantime, since a peripheral circuit can be embedded in the same chip, it is possible to rapidly read a signal out of an imaging element, and to achieve speeding up and high resolution.

### SUMMARY

In the field of the imaging devices, there has been a demand for reduction of noise occurring in an imaging device.

One non-limiting and exemplary embodiment provides an imaging device with reduced noise.

In one general aspect, the techniques disclosed here feature an imaging device including a first pixel and a second pixel each provided with a photoelectric converter that converts light into electric charges and a first transistor connected to the photoelectric converter, first wiring that is connected to one of a source and a drain of the first transistor of the first pixel, second wiring that is different from the first wiring and is connected to one of a source and a drain of the first transistor of the second pixel, a first voltage line to which a first voltage is applied, and a first amplification circuit that is connected to the first voltage line, amplifies the first voltage, and outputs the amplified first voltage to the first wiring and the second wiring.

According to the present disclosure, it is possible to provide an imaging device with reduced noise.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a diagram schematically illustrating an exemplary circuit configuration of an imaging device according to Embodiment 1;

FIG. 2 is a diagram illustrating an exemplary circuit configuration of a pixel in the imaging device according to the Embodiment 1;

FIG. 3 is a block diagram illustrating a circuit configuration to generate a second power supply voltage in FIG. 2;

FIG. 4 is a diagram illustrating detailed circuit configurations of a voltage generation circuit and a buffer circuit illustrated in FIG. 3;

FIG. 5 is a diagram schematically illustrating an exemplary circuit configuration of an imaging device according to Modified Example 1 of the Embodiment 1;

FIG. 6 is a diagram schematically illustrating an exemplary circuit configuration of an imaging device according to Modified Example 2 of the Embodiment 1;

FIG. 7 is a diagram schematically illustrating an exemplary circuit configuration of an imaging device according to Modified Example 3 of the Embodiment 1;

FIG. 8 is a diagram schematically illustrating an exemplary circuit configuration of buffer circuits included in an imaging device according to Embodiment 2;

FIG. 9 is a diagram schematically illustrating an exemplary circuit configuration of buffer circuits included in an imaging device according to Embodiment 3;

FIG. 10 is a timing chart for explaining an operation of the buffer circuit included in the imaging device according to the Embodiment 3;

FIG. 11A is a diagram schematically illustrating an exemplary circuit configuration of buffer circuits according to Modified Example 1 of the Embodiment 3;

FIG. 11B is a diagram schematically illustrating an exemplary circuit configuration of buffer circuits according to a modification of the Modified Example 1 of the Embodiment 3;

FIG. 12 is a diagram schematically illustrating an exemplary circuit configuration of buffer circuits included in an imaging device according to Embodiment 4;

FIG. 13 is a diagram illustrating an exemplary circuit configuration of a pixel in an imaging device according to Embodiment 5;

FIG. 14 is a block diagram illustrating a circuit configuration to generate the second power supply voltage in FIG. 13; and

FIG. 15 is a diagram schematically illustrating a camera system according to Embodiment 6.

### DETAILED DESCRIPTIONS

Underlying Knowledge Forming Basis of the Present Disclosure

There has been known a technique for bringing about a negative feedback of an electric potential of floating diffusion (hereinafter also referred to as “FD”) in order to reduce kTC noise (also referred to as “reset noise”) that is generated at the time of resetting a pixel (Japanese Unexamined Patent Application Publication No. 2016-127593 and International Publication No. WO 2020/079884, for example). Here, reset of a pixel will also be referred to as “reset of FD” or simply as “reset”). In order to implement this technique, it is necessary to apply a reference voltage for operating a negative feedback amplifier to the pixel in addition to a power supply voltage. At the time of a negative feedback operation, a voltage generation circuit to supply this reference voltage has a role for feeding an operating current for the negative feedback amplifier in the pixel, and a voltage drop is caused by parasitic resistance of wiring to supply the reference voltage and by an electric current from the negative feedback amplifier flowing thereon. As a consequence, there is a problem that the reference voltage to be applied to a pixel on a central column of a pixel array is different from that to be applied to a pixel on a peripheral column of the pixel array. Due to a deviation of these reference voltages, there occurs a difference in amount of reduction of reset noise associated with in-pixel feedback between the central column of the pixel array and the peripheral column thereof. As a consequence, an image containing uneven noise distribution depending on the columns of the pixel array may be outputted from an imaging device, thus leading to deterioration in image quality performances.

The inventors of the present disclosure have conducted investigations for the purpose of noise reduction and have reached the concept of the present disclosure. One non-limiting and exemplary embodiment of the present application provides an imaging device that realizes reduction of image noise by effectively suppressing a deviation of reference voltages depending on columns of a pixel array.

An outline of an aspect of the present disclosure is as follows.

### [Item 1]

An imaging device including:
a first pixel and a second pixel each including a photoelectric converter that converts light into electric charges, and a first transistor connected to the photoelectric converter;
first wiring that is connected to one of a source and a drain of the first transistor of the first pixel;
second wiring that is different from the first wiring and is connected to one of a source and a drain of the first transistor of the second pixel;
a first voltage line to which a first voltage is applied; and
a first amplification circuit that is connected to the first voltage line, amplifies the first voltage, and outputs the amplified first voltage to the first wiring and the second wiring.

### [Item 2]

The imaging device according to item 1, in which the first transistor includes a gate connected to the photoelectric converter, and outputs a signal corresponding to an amount of the electric charges.

### [Item 3]

The imaging device according to item 1, in which another one of the source and the drain of the first transistor is connected to the photoelectric converter.

### [Item 4]

The imaging device according to any one of items 1 to 3, in which an output terminal of the first amplification circuit is connected to an output terminal of the second amplification circuit.

### [Item 5]

The imaging device according to any one of items 1 to 3, in which
the first amplification circuit includes
a second transistor, and
a third transistor connected in series to the second transistor,
a gate of the second transistor is connected to the first voltage line, and
a first node between the second transistor and the third transistor is connected to the first wiring.

### [Item 6]

The imaging device according to item 5, further including:
a second voltage line to which a second voltage is applied; and
a third voltage line to which a third voltage is applied, in which
the second transistor and the third transistor are connected in series between the second voltage line and the third voltage line.

### [Item 7]

The imaging device according to item 5 or 6, in which a voltage for causing the third transistor to function as a current source and a voltage for turning on the third transistor are alternately supplied to a gate of the third transistor.

### [Item 8]

The imaging device according to item 6, in which the first amplification circuit includes a switch connected between the second voltage line and a gate of the third transistor.

### [Item 9]

The imaging device according to item 6, in which the first amplification circuit includes a switch connected between the third voltage line and the first node.

### [Item 10]

The imaging device according to item 6, further including:
a fourth voltage line to which a fourth voltage is applied, in which
the first amplification circuit includes a switch connected between the fourth voltage line and the first node.

### [Item 11]

The imaging device according to item 1 or 2, in which each of the first pixel and the second pixel includes a second transistor connected between another one of the source and the drain of the first transistor and the photoelectric converter.

### [Item 12]

The imaging device according to any one of items 1 to 11, further including:
a voltage generation circuit that supplies the first voltage to the first voltage line.

To be more precise, an imaging device according to an aspect of the present disclosure includes multiple pixels each provided with a photoelectric converter that converts light into electric charges and an amplification transistor that outputs a signal corresponding to an amount of the electric charges, first wiring that is connected to one of a source and a drain of the amplification transistor of a first pixel out of the multiple pixels, a first voltage line to which a first voltage is applied, and a first amplification circuit that is connected to the first voltage line, amplifies the first voltage, and outputs the amplified first voltage to the first wiring (see FIG. 4).

Accordingly, the first amplification circuit is provided between the first voltage line to which the first voltage for generating a reference voltage is applied and the first wiring connected to one of the source and the drain of the amplification transistor. Thus, a voltage drop attributed to wiring resistance of the first voltage line is reduced and accuracy of the reference voltage to be applied to the amplification transistor is improved. As a consequence, a deviation of the reference voltages depending on columns of a pixel array is effectively suppressed, and reduction in image noise is achieved.

Here, the imaging device may further include second wiring being different from the first wiring and connected to one of a source and a drain of the amplification transistor of a second pixel being different from the first pixel, and a second amplification circuit that is connected to the first voltage line, amplifies the first voltage, and outputs the amplified first voltage to the second wiring (see FIG. 4). Accordingly, when the amplification circuits are provided to two columns, respectively, for example, a voltage drop attributed to the wiring resistance of the first voltage line is reduced in each of the two columns.

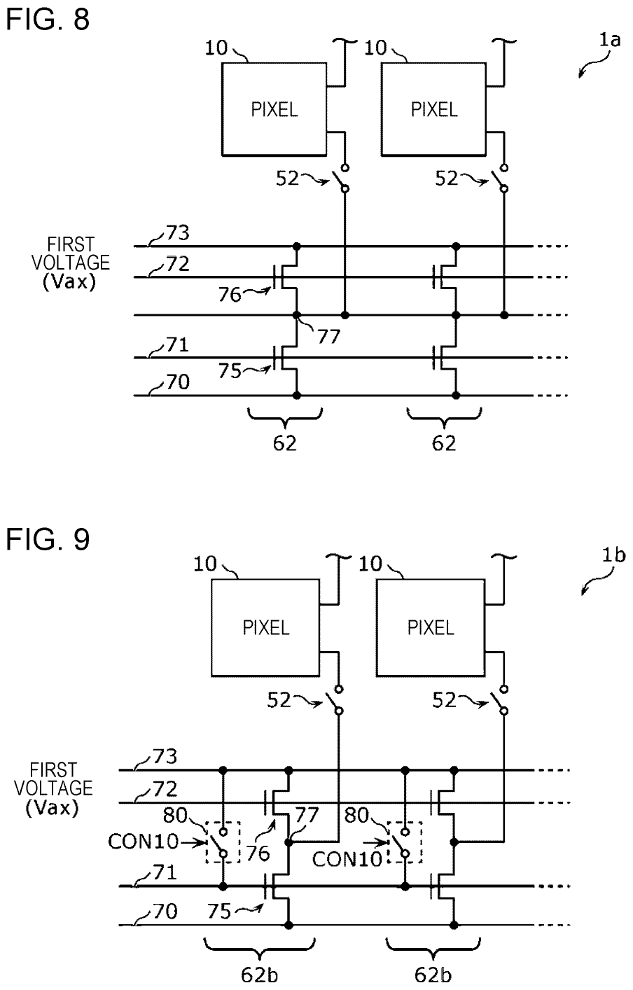

Meanwhile, the output terminal of the first amplification circuit may be connected to the output terminal of the second amplification circuit (see FIG. 8). Thus, output terminals of the two amplification circuits are connected to each other, thereby reducing a variation in output voltage between the amplification circuits attributed to a difference in characteristics of the transistors constituting the amplification circuits.

In the meantime, the first amplification circuit may include the first transistor and the second transistor connected in series to the first transistor. The gate of the first transistor may be connected to the first voltage line and a first node between the first transistor and the second transistor may be connected to the first wiring (see FIG. 4). In this way, the first amplification circuit is realized by using fewer constituents, so that an increase in area of column circuits in the imaging device is suppressed.

Meanwhile, the imaging device may further include a second voltage line to which a second voltage is applied, and a third voltage line to which a third voltage is applied. Here, the first transistor and the second transistor may be connected in series between the second voltage line and the third voltage line (see FIG. 4). Accordingly, the first amplification circuit can be operated by using a power supply of its own which is different from that for the column circuits.

In the meantime, a voltage for causing the second transistor to function as a current source and a voltage for turning on the second transistor may be alternately supplied to the gate of the second transistor (FIG. 9). In this way, the second transistor constituting the first amplification circuit can be provided with a mode of being operated as the current source and a mode of rapidly attracting a potential of FD.

As an example thereof, the first amplification circuit may include a switch connected between the second voltage line and the gate of the second transistor (see FIG. 9).

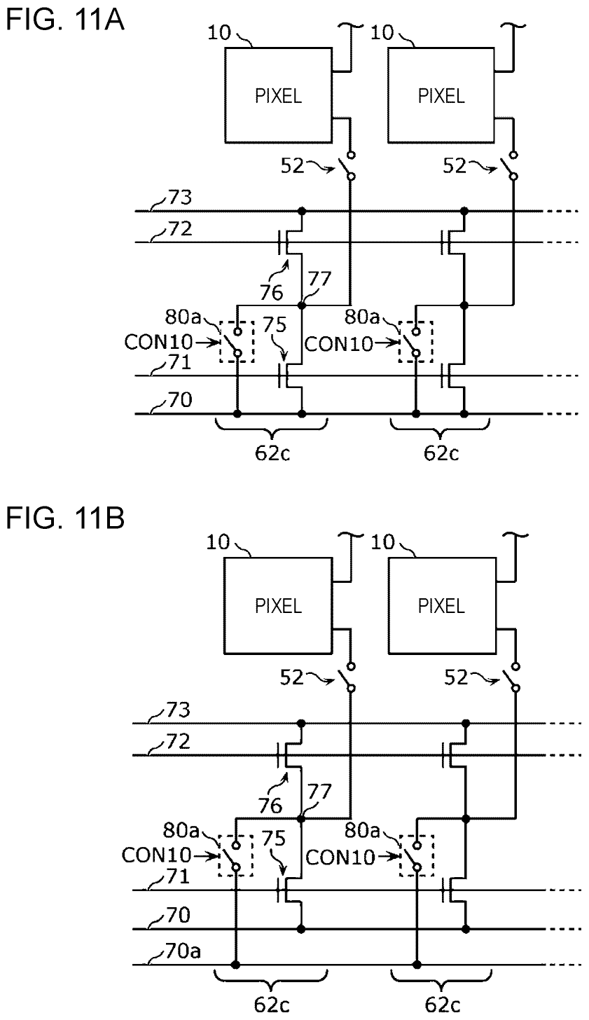

Meanwhile, the first amplification circuit may include a switch connected between the third voltage line and the first node (see FIG. 11A). This makes it possible to rapidly attract the potential of the FD to a target reset potential.

Here, the imaging device may further include a fourth voltage line to which a fourth voltage is applied, and the first amplification circuit may include a switch connected between the fourth voltage line and the first node (see FIG. 11B). This makes it possible to rapidly attract the potential of the FD to the fourth voltage as desired.

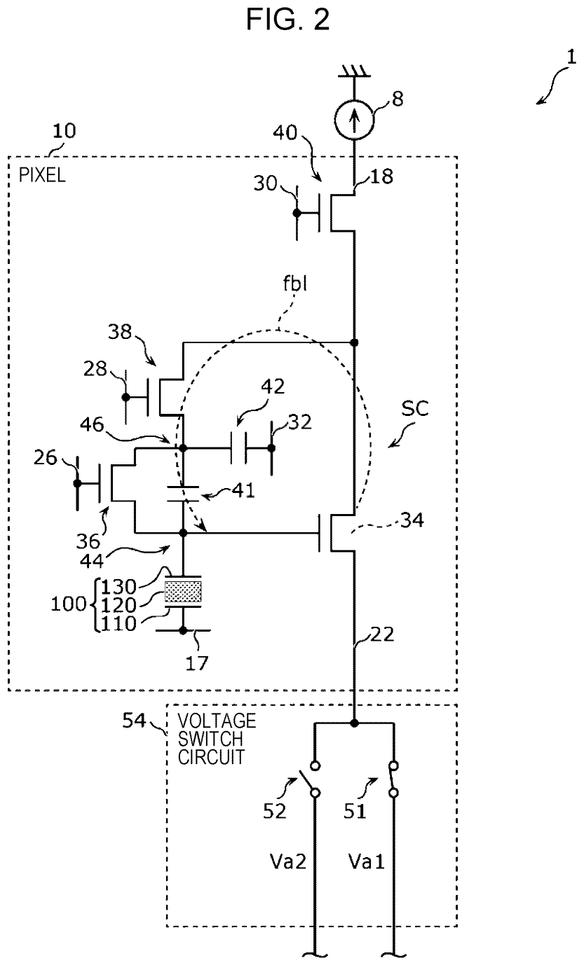

Meanwhile, each of the pixels may include a reset transistor connected between another one of the source and the drain of the amplification transistor and the photoelectric converter (see FIG. 2). This makes it possible to reduce noise to be generated at the time of resetting the FD.

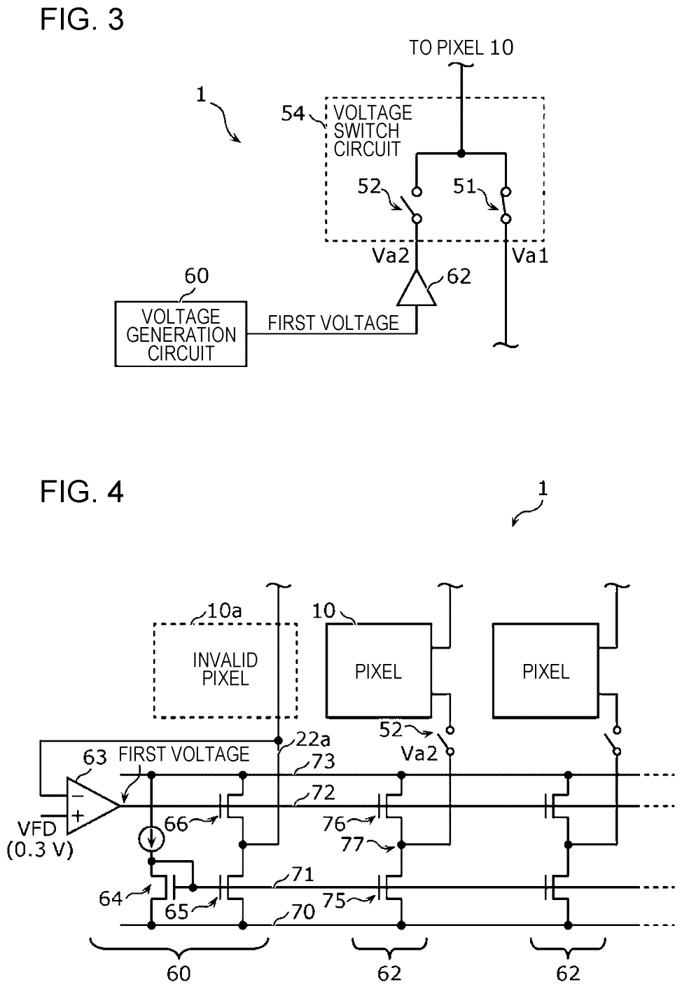

The imaging device may further include the voltage generation circuit that supplies the first voltage to the first voltage line (see FIG. 3). In this way, it is no longer necessary to supply the first voltage from outside.

Embodiments of the present disclosure will be described below with reference to the drawings. Each of the embodiments described below represents a specific example of the present disclosure. Numerical values, shapes, materials, constituents, layout positions and modes of connection of the constituents, signal waveforms, timing of signals, and the like cited in the following embodiments are mere examples and are not intended to limit the scope of the present disclosure. In the meantime, the drawings are not always illustrated precisely. In the drawings, substantially the same configurations are denoted by the same reference signs and overlapping explanations will be omitted or simplified. Meanwhile, the drawings may only partially illustrate locations related to the relevant explanations. Moreover, the mode of “connection” includes not only a case of directly connecting A to B but also a case of indirectly connecting A to B with another circuit element interposed therebetween.

### Embodiment 1

### Circuit Configuration

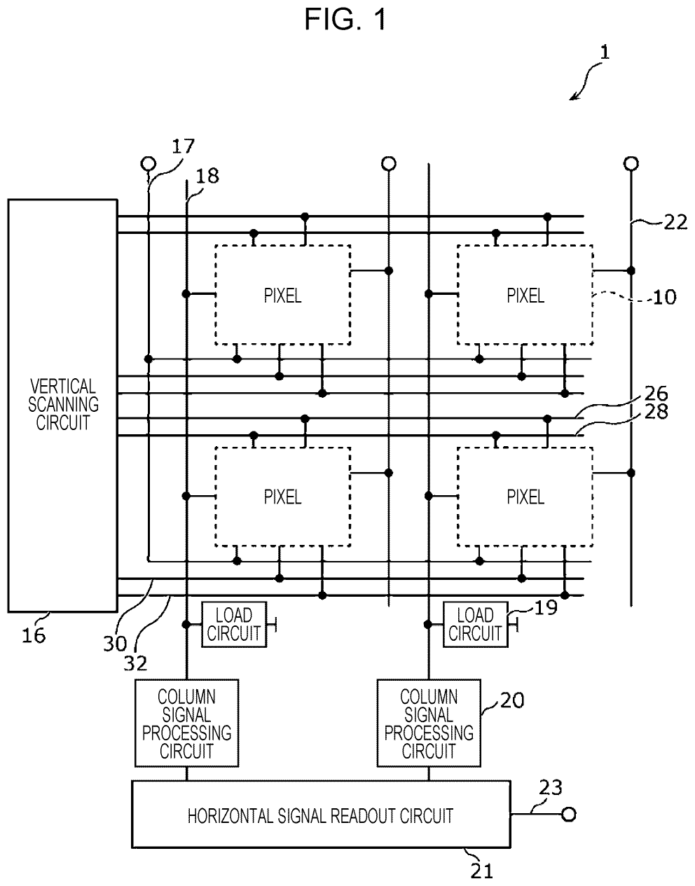

Circuits of an imaging device according to Embodiment I will be described with reference to FIG. 1 to begin with.

FIG. 1 is a diagram schematically illustrating an exemplary circuit configuration of an imaging device 1 according to the present embodiment. The imaging device 1 illustrated in FIG. 1 includes pixels 10 and peripheral circuits.

The pixels 10 are two-dimensionally arranged on a semiconductor substrate, thus forming a pixel region. The semiconductor substrate is not limited to a substrate which is entirely formed from a semiconductor. The semiconductor substrate may be a substrate such as an insulating substrate provided with a semiconductor layer on a surface to be provided with the pixel region.

In the illustrated example, the pixels 10 are arranged in a row direction and a column direction. In the present specification, the row direction and the column direction mean directions of extension of rows and columns, respectively. In other words, a vertical direction is the column direction while a horizontal direction is the row direction.

Here, the pixels 10 may be one-dimensionally arranged instead. In other words, the imaging device 1 may be a line sensor.

Each of the pixels 10 is connected to a power supply line 22. The power supply line 22 is power supply wiring from a source follower power supply. A predetermined power supply voltage is supplied to each pixel 10 through the power supply line 22. Each of the pixels 10 includes a photoelectric converter, which is provided with a photoelectric conversion film laminated on the semiconductor substrate. The photoelectric converter is provided on the semiconductor substrate while interposing a wiring layer therebetween. Meanwhile, as illustrated in FIG. 1, the imaging device 1 includes an accumulation control line 17 for applying the same constant voltage to all of the photoelectric converters.

The peripheral circuits include a vertical scanning circuit 16, load circuits 19, column signal processing circuits 20, and a horizontal signal readout circuit 21. In the illustrated configuration, the column signal processing circuits 20 and the load circuits 19 are disposed at the respective columns of the pixels 10 that are two-dimensionally arranged. That is to say, in this example, the peripheral circuits include the multiple column signal processing circuits 20 and the multiple load circuits 19.

The vertical scanning circuit 16 is connected to address signal lines 30 and reset signal lines 26. The vertical scanning circuit 16 is also referred to as a row scanning circuit. The vertical scanning circuit 16 selects the pixels 10 disposed on the respective rows on the row basis by applying a predetermined voltage to the address signal lines 30 or the reset signal lines 26. In this way, readout of signal voltages of selected pixels 10 or reset of the pixels 10 is executed.

In the illustrated example, the vertical scanning circuit 16 is also connected to sensitivity adjustment lines 32. The vertical scanning circuit 16 can supply a predetermined voltage to the pixels 10 through the sensitivity adjustment lines 32. As will be described later in detail, in the present disclosure, each of the pixels 10 includes one or more capacitive elements within the relevant pixel. In the present specification, the “capacitive element (a capacitor)” means a structure formed by sandwiching a dielectric body such as an insulating film between electrodes. An “electrode” in the present specification is not limited only to an electrode formed from a metal, but is interpreted to encompass a wide range of electrodes such as a polycrystalline silicon layer.

The pixels 10 disposed on the respective columns are electrically connected to the column signal processing circuit 20 through vertical signal lines 18 corresponding to the respective columns (such electrical connection may also be hereinafter simply referred to as “connection”). The load circuits 19 are electrically connected to the vertical signal lines 18. The column signal processing circuit 20 carries out noise suppression signal processing as represented by correlated double sampling, analog-to-digital conversion (AD conversion), and so forth. The column signal processing circuit 20 is also referred to as a row signal accumulation circuit. The horizontal signal readout circuit 21 is electrically connected to the column signal processing circuits 20 that are provided corresponding to the columns of the pixels 10. The horizontal signal readout circuit 21 sequentially reads out signals from the column signal processing circuits 20 and outputs the signals to a horizontal common signal line 23. The horizontal signal readout circuit 21 is also referred to as a column scanning circuit.

FIG. 2 is a diagram illustrating an exemplary circuit configuration of a pixel 10 in the imaging device 1 according to the Embodiment 1. The pixel 10 includes a photoelectric converter 100 that subjects incident light to photoelectric conversion, and a signal detection circuit SC that detects a signal generated by the photoelectric converter 100. The photoelectric converter 100 typically has such a structure that a photoelectric conversion film 120 is sandwiched between a counter electrode 110 and a pixel electrode 130. The photoelectric conversion film 120 is stacked on the semiconductor substrate on which the pixel 10 is formed. The photoelectric conversion film 120 is formed from an organic material or an inorganic material such as amorphous silicon.

The counter electrode 110 is provided on a light receiving surface side of the photoelectric conversion film 120. The counter electrode 110 is formed from a transparent conductive material. Indium tin oxide (ITO) is an example of the transparent conductive material. The pixel electrode 130 is provided on a side opposed to the counter electrode 110 while interposing the photoelectric conversion film 120 therebetween. The pixel electrode 130 collects electric charges generated by the photoelectric conversion in the photoelectric conversion film 120. The pixel electrode 130 is made of a metal such as aluminum and copper, or polycrystalline silicon being doped with an impurity and thus provided with conductivity, and the like.

As illustrated in FIG. 2, the counter electrode 110 is connected to the accumulation control line 17. The pixel electrode 130 is connected to an electric charge accumulation region 44. The electric charge accumulation region 44 is also referred to as FD or an FD node. Control of an electric potential of the counter electrode 110 through the accumulation control line 17 enables the pixel electrode 130 to collect any one of a hole and an electron out of a hole-electron pair generated by the photoelectric conversion. When the hole is used as a signal electric charge, an electric potential of the counter electrode 110 may be set higher than that of the pixel electrode 130. The following description will exemplify the case of using the hole as the signal electric charge. For example, a voltage around 10 V is applied to the counter electrode 110 through the accumulation control line 17. Thus, the signal electric charge is accumulated in the electric charge accumulation region 44. Needless to say, the electron may be used as the signal electric charge instead.

The signal detection circuit SC provided to the pixel 10 includes an amplification transistor 34, a reset transistor 36, a first capacitive element 41, and a second capacitive clement 42. In the illustrated configuration, the second capacitive element 42 has a larger capacitance value than that of the first capacitive element 41.

In the configuration exemplified in FIG. 2, a gate of the reset transistor 36 is connected to the reset signal line 26. Meanwhile, one of a source and a drain of the reset transistor 36 as well as one of electrodes of the first capacitive element 41 are connected to the electric charge accumulation region 44. That is to say, these constituents have electrical connection to the pixel electrode 130. The other one of the source and the drain of the reset transistor 36 as well as the other one of electrodes of the first capacitive clement 41 are connected to one of electrodes of the second capacitive element 42. In other words, the first capacitive element 41 is connected between the source and the drain of the reset transistor 36. In the following description, a node including a connecting point of the first capacitive element 41 to the second capacitive element 42 may be referred to as a reset drain node 46 as appropriate.

Of the electrodes of the second capacitive element 42, the electrode not connected to the reset drain node 46 is connected to the sensitivity adjustment line 32. An electric potential of the sensitivity adjustment line 32 is set to 0 V, for example. The electric potential of the sensitivity adjustment line 32 need not be fixed when the imaging device 1 is in operation. For instance, a pulse voltage may be supplied from the vertical scanning circuit 16 (scc FIG. 1).

As illustrated in FIG. 2, a gate of the amplification transistor 34 is connected to the electric charge accumulation region 44. In other words, the gate of the amplification transistor 34 has electrical connection to the pixel electrode 130. One of a source and a drain of the amplification transistor 34 (which is the drain in the case where the amplification transistor 34 is an n-channel MOSFET, for example) is connected to the power supply line 22. The other one of the source and the drain of the amplification transistor 34 is connected to the vertical signal line 18, which is a signal line to transmit an electric signal outputted from the amplification transistor 34. A source follower circuit is formed from the amplification transistor 34 and the load circuit 19 (see FIG. 1). The amplification transistor 34 amplifies a signal generated by the photoelectric converter 100.

As illustrated in FIG. 2, the pixel 10 includes an address transistor 40. The address transistor 40 is also referred to as a row selection transistor. A source or a drain of the address transistor 40 is connected to one of the source and drain of the amplification transistor 34 which is not connected to the power supply line 22. A gate of the address transistor 40 is connected to an address signal line 30.

A voltage corresponding to an amount of signal electric charges accumulated in the electric charge accumulation region 44 is applied to the gate of the amplification transistor 34. The amplification transistor 34 amplifies this voltage. The voltage amplified by the amplification transistor 34 is selectively read out as an electric signal by the address transistor 40.

As illustrated in FIG. 2, the signal detection circuit SC includes a feedback loop fb1. The signal detection circuit SC includes a feedback transistor 38 located on the feedback loop fb1. One of a source and a drain of the feedback transistor 38 is connected to one of the source and the drain of the amplification transistor 34 which is connected to the vertical signal line 18. The other one of the source and the drain of the feedback transistor 38 is connected to the reset drain node 46. A gate of the feedback transistor 38 is connected to a feedback control line 28.

The feedback loop fb1 is a loop for causing the output from the amplification transistor 34 to be negatively fed back to the feedback transistor 38. In other words, an electric potential of the electric charge accumulation region 44 is negatively fed back to the feedback transistor 38 through the amplification transistor 34. In the example illustrated in FIG. 2, the feedback loop fb1 is provided to each pixel 10 instead of extending across two or more pixels 10. Here, in the configuration exemplified in FIG. 2, the output from the amplification transistor 34 is used as a reference voltage for resetting the electric charge accumulation region 44. The feedback loop fb1 means a loop that extends from the electric charge accumulation region 44 to the electric charge accumulation region 44 again while passing through the amplification transistor 34, the feedback transistor 38, and either the first capacitive element 41 or the reset transistor 36.

In the present embodiment, feedback for noise cancellation can be carried out in cach of the pixels 10. In this way, it is possible to carry out noise cancellation rapidly without being affected by a time constant of the vertical signal lines 18. Here, in the circuit configuration exemplified in FIG. 2, the output voltage from the amplification transistor 34 is applied to the reset transistor 36. This configuration can reduce a change in voltage of the electric charge accumulation region 44 between points before and after turning off the reset transistor 36, thus realizing noise suppression even more rapidly.

In the configuration illustrated in FIG. 2, a voltage switch circuit 54 is connected to the power supply line 22. The voltage switch circuit 54 includes a set of a first switch 51 and a second switch 52. The voltage switch circuit 54 switches between a first power supply voltage Va1 and a second power supply voltage Va2 to be supplied to the power supply line 22. The first power supply voltage Va1 is a power supply voltage for readout, which is set to 3.3 V, for example. The second power supply voltage Va2 is a power supply voltage for noise cancellation, which is set to 0.3 V, for example. The voltage switch circuit 54 may be provided to each pixel or shared by two or more pixels 10. The above-described circuit configuration can reduce an impact of the kTC noise.

A constant current source 8 is connected to the vertical signal line 18. When the address transistor 40 is turned on, the source follower circuit is formed from the address transistor 40, the amplification transistor 34, and the constant current source 8. The signal corresponding to the signal electric charges accumulated in the electric charge accumulation region 44 is outputted to the vertical signal line 18 and is read out to the outside. Here, the constant current source 8 may be provided to each pixel 10. The constant current source 8 may be shared by two or more pixels 10 in order to reduce the number of elements per pixel.

When resetting the electric charge accumulation region 44, the address transistor 40 is turned off and the amplification transistor 34 is electrically isolated from the vertical signal line 18. Meanwhile, the feedback transistor 38 is turned on. In the meantime, the second switch 52 of the voltage switch circuit 54 is turned on. That is to say, the second power supply voltage Va2 is applied to one of the source and the drain of the amplification transistor 34, which is not connected to the vertical signal line 18 (namely, the power supply line 22). Moreover, by turning on the reset transistor 36, the electric charge accumulation region 44 is reset and the voltage of the electric charge accumulation region 44 is set to the reference voltage.

Next, the reset transistor 36 is turned off. In this instance, the signal detection circuit SC forms the feedback loop with an amplification factor equivalent to −A×B times. For this reason, the kTC noise in the electric charge accumulation region 44 that may occur in the case of turning off the reset transistor 36 is suppressed to 1/(1+A×B) times. In this way, it is possible to suppress the kTC noise.

Meanwhile, the voltage of the feedback control line 28 is set between a high level and a low level, such as an intermediate voltage in a noise suppression period. In this case, an operating band of the feedback transistor 38 becomes a second band which is narrower than a first band.

In the state where the second band is narrower than the operating band of the amplification transistor 34, thermal nose that may be generated in the feedback transistor 38 is suppressed to 1/(1+A×B)^{1/2} times by the feedback loop fb1. In this state, the voltage of the feedback control line 28 is set to the low level and the feedback transistor 38 is turned off. Then, the kTC noise remaining in the electric charge accumulation region 44 at this point has a value equivalent to a square sum of the kTC noise attributable to the reset transistor 36 and the kTC noise attributable to the feedback transistor 38.

A capacitance of the first capacitive element 41 will be defined as Cs and a capacitance of the electric charge accumulation region 44 will be defined as CFD. In this case, the kTC noise of the feedback transistor 38 generated in the state without suppression by the feedback is equivalent to (CFD/Cs)^{1/2} times as large as the kTC noise of the reset transistor 36 generated in the state without suppression by the feedback. In consideration thereof, the kTC noise in the case with the feedback is suppressed to {1+ (1+A×B)×CFD/Cs}^{1/2}/(1+A×B) times as large as that in the case without the feedback.

In a readout period, a voltage of the address signal line 30 is set to a high level while turning the address transistor 40 on, and then the voltage switch circuit 54 is controlled such that the voltage of the other one of the source and the drain of the amplification transistor 34 (namely, the power supply line 22) becomes equal to the first power supply voltage Va1. In this state, the source follower circuit is formed from the amplification transistor 34 and the constant current source 8. The vertical signal line 18 is set to such a voltage corresponding to the signal electric charges accumulated in the electric charge accumulation region 44. In this instance, the amplification factor of the source follower circuit is around 1 times.

The voltage of the electric charge accumulation region 44 changes from the reference voltage in an amount corresponding to the electric signal generated by the photoelectric converter 100. The voltage of the electric charge accumulation region 44 is outputted to the vertical signal line 18 at the amplification factor around 1 times.

Random noise means fluctuation of the output when the signal electric charge generated by the photoelectric converter 100 is equal to 0, or in other words, the kTC noise. The kTC noise is suppressed to {1+ (1+A×B)×CFD/Cs}^{1/2}/(1+A×B) times in the noise suppression period. Moreover, the kTC noise is outputted to the vertical signal line 18 at the amplification factor around 1 times in the readout period. As a consequence, it is possible to obtain favorable image data with suppressed random noise.

Here, each of the amplification transistor 34, the reset transistor 36, the feedback transistor 38, and the address transistor 40 may be an n-channel MOSFET or a p-channel MOSFET. All of these transistors do not always have to uniformly adopt one of the n-channel MOSFET or the p-channel MOSFET. Note that the n-channel MOSFET will be hereinafter simply referred to as “NMOS” while the p-channel MOSFET will be hereinafter simply referred to as “PMOS”.

FIG. 3 is a block diagram illustrating a circuit configuration to generate the second power supply voltage Va2 in FIG. 2. FIG. 3 illustrates a voltage generation circuit 60 that supplies a first voltage being a fixed voltage, and a buffer circuit 62 that amplifies the first voltage supplied from the voltage generation circuit 60 and outputs the amplified voltage as the second power supply voltage Va2 to the second switch 52. The buffer circuit 62 is an example of a first amplification circuit that amplifies the first voltage, and is an impedance converter with a voltage gain of 1. The voltage generation circuit 60 may be included in the imaging device 1 or provided outside of the imaging device 1. In the case where the voltage generation circuit 60 is provided outside of the imaging device 1, the first voltage outputted from the voltage generation circuit 60 is supplied to the buffer circuit 62 through wiring, a connection terminal, and the like.

FIG. 4 is a diagram illustrating detailed circuit configurations of the voltage generation circuit 60 and the buffer circuit 62 illustrated in FIG. 3. Note that FIG. 4 omits illustration of wiring and circuits related to the first power supply voltage Va1 for the convenience of explanation. The same applies to other drawings to be described later. In the present embodiment, a source follower circuit using NMOS transistors is formed as the buffer circuit 62 to be provided to each column of the pixel array. The buffer circuit 62 includes an amplification transistor 76 functioning as a source follower, which represents an example of a first transistor, and a current source transistor 75 functioning as a current source, which represents an example of a second transistor. A voltage line 73 represents an example of a second voltage line for supplying a power supply voltage being an example of a second voltage. A voltage line 70 represents an example of a third voltage line for supplying a ground voltage being an example of a third voltage. A voltage for the current source to operate the current source transistor 75 as the current source is supplied from the voltage generation circuit 60 to a voltage line 71. The fixed first voltage from the voltage generation circuit 60 is applied to a gate of the amplification transistor 76 through a voltage line 72 that represents an example of a first voltage line.

A voltage obtained by amplifying the first voltage by the buffer circuit 62 (namely, the second power supply voltage Va2) may be outputted from an output terminal 77 being a first node between the amplification transistor 76 and the current source transistor 75, and may be applied to the power supply line 22 being an example of first wiring through the second switch 52. Here, the first wiring is wiring to which the output voltage amplified by the buffer circuit 62 is to be applied. Meanwhile, two buffer circuits 62 illustrated in FIG. 4 represent an example of a first amplification circuit to be connected to the first voltage line and configured to amplify the first voltage and to output the amplified voltage to the first wiring, and an example of a second amplification circuit to be connected to the first voltage line and configured to amplify the first voltage and to output the amplified voltage to second wiring, respectively.

The voltage generation circuit 60 supplies the first voltage to the buffer circuit 62 through the voltage line 72 and supplies the voltage for the current source thereto through the voltage line 71 by using an invalid pixel 10a included in the imaging device 1. The invalid pixel 10a is one of the pixels 10 provided to the imaging device 1, which is not employed for an imaging usage. The voltage generation circuit 60 includes an operational amplifier 63, and NMOS transistors 64 to 66. The transistors 65 and 66 constitute a replication circuit that has the same configuration as that of the buffer circuit 62. The transistors 64 and 65 constitute a current mirror. A fixed reference voltage VFD (such as 0.3 V) is inputted to a non-inverting input terminal of the operational amplifier 63 while an inverting input terminal of the operational amplifier 63 is connected to a power supply line 22a for the invalid pixel 10a. An output terminal of the operational amplifier 63 is connected to gates of the transistor 66 and of the amplification transistors 76 of the respective buffer circuits 62.

According to the above-described configuration, the operational amplifier 63 is subjected to negative feedback. As a consequence, output voltages from the power supply line 22a of the invalid pixel 10a connected to the inverting input terminal of the operational amplifier 63 as well as from the respective buffer circuits 62 (namely, the second power supply voltage Va2) have the same value as the fixed reference voltage VFD (such as 0.3 V) inputted to the non-inverting input terminal of the operational amplifier 63. Meanwhile, due to the function of the current mirror, a current which is a certain number of times (such as A times) as large as the current flowing on the transistor 64 flows on the transistor 65, and a current which is a certain number of times (such as B times) as large as the current flowing on the transistor 64 also flows on the current source transistors 75 of the respective buffer circuits 62. The aforementioned value A is expressed as (a WL ratio of the transistor 65) divided by (a WL ratio of the transistor 64), while the aforementioned value B is expressed as (a WL ratio of the current source transistor 75) divided by (the WL ratio of the transistor 64). The WL ratio is defined as a gate width divided by a gate length.

Accordingly, even in a state where the first voltage is applied from the operational amplifier 63 to the voltage line 72 and the current for a feedback operation is flowing, no current flows from each column toward the voltage line 72 due to the existence of the buffer circuit 62. For this reason, the first voltage applied to the voltage line 72 is not affected by the current flowing in the course of noise cancellation irrespective of the position of the column. Therefore, the second power supply voltage Va2 being the voltage equal to the reference voltage VFD (such as 0.3 V) can be applied to the power supply line 22 on any column.

By applying the second power supply voltage Va2 equal to the reference voltage VFD to the power supply line 22 on each column through the buffer circuit 62, the current flowing in the course of noise cancellation will flow to the buffer circuit 62 instead of flowing to the voltage line 72 that transmits the first voltage. Thus, it is possible to suppress a voltage drop attributed to the previously generated parasitic capacitance on the wiring to supply the reference voltage. Moreover, a variation in amount of noise reduction in the course of noise cancellation depending on the column position is improved, thereby suppressing deterioration of an image signal to be read out.

### Modified Example 1

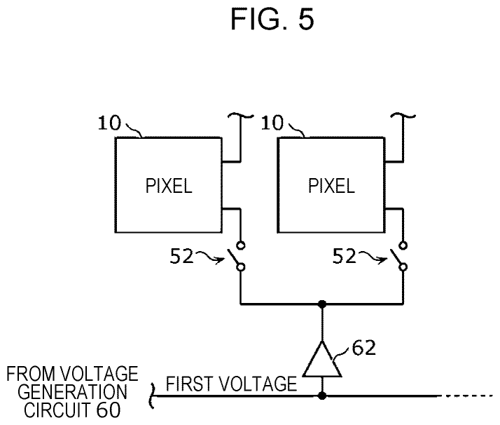

FIG. 5 is a diagram schematically illustrating an exemplary circuit configuration of an imaging device according to Modified Example 1 of the Embodiment 1. The present modified example is different from the Embodiment 1 in that the buffer circuit 62 is shared by the columns of the pixel array. Specifically, the output terminal 77 of one buffer circuit 62 is connected to the second switches 52 provided to the respective power supply lines 22 of the columns of the pixel array, respectively. This makes it possible to reduce the number of the buffer circuits 62 necessary for the imaging device as compared to the case of providing the buffer circuit 62 to each column, thereby reducing the area of the buffer circuits.

### Modified Example 2

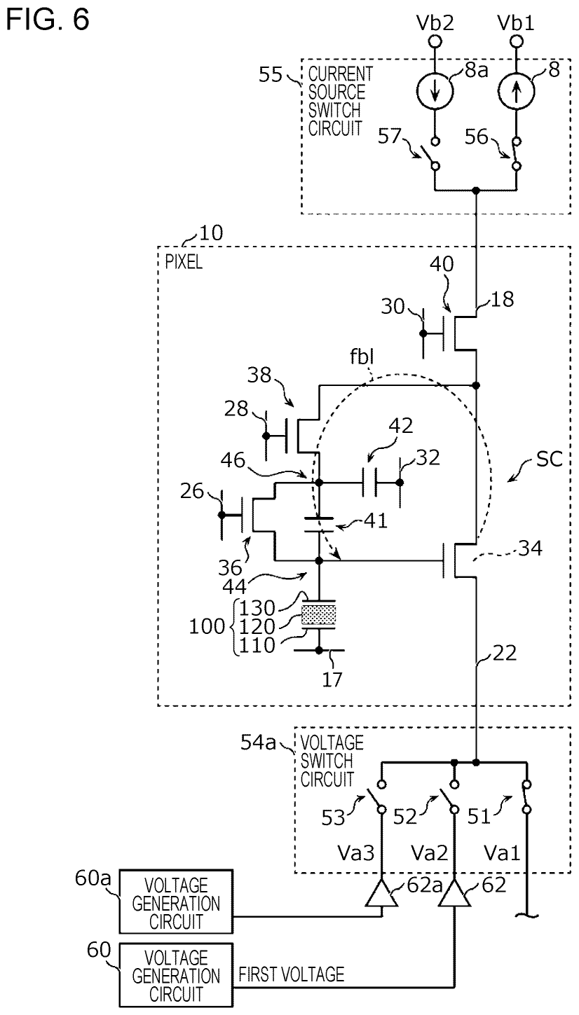

FIG. 6 is a diagram schematically illustrating an exemplary circuit configuration of an imaging device according to Modified Example 2 of the Embodiment 1. In the present modified example, a circuit configuration for noise cancellation is different from that of the Embodiment 1. In the present modified example, the imaging device includes a current source switch circuit 55 as a constant current source for noise cancellation. The current source switch circuit 55 includes the constant current source 8 for readout connected to a voltage Vb1, a switch 56 that switches between connection and non-connection of the constant current source 8 to the vertical signal line 18, a constant current source 8a for noise cancellation connected to a voltage Vb2, and a switch 57 that switches between connection and non-connection of the constant current source 8a to the vertical signal line 18.

Meanwhile, in the present modified example, the imaging device includes a voltage switch circuit 54a instead of the voltage switch circuit 54 of the Embodiment 1. In addition to the configuration of the voltage switch circuit 54 of the Embodiment 1, the voltage switch circuit 54a includes a third switch 53 that switches between connection and non-connection of the power supply line 22 to a third power supply voltage Va3 being a reference voltage for pre-resetting in noise cancellation. One type of the reference voltage (namely, the first power supply voltage Va1) serving as the voltage for readout, and two types of reference voltages (namely, the second power supply voltage Va2 and the third power supply voltage Va3) serving as the voltage for noise cancellation are selectively supplied by using this voltage switch circuit 54a. Specifically, the first power supply voltage Va1 is applied to the power supply line 22 through the first switch 51 at the time of readout. The second power supply voltage Va2 is supplied to the power supply line 22 through the second switch 52 as with the Embodiment 1 when carrying out the feedback operation for noise cancellation. The third power supply voltage Va3 is supplied to the power supply line 22 through the third switch 53 when pre-resetting the electric potential of the FD before the feedback operation.

In the present modified example, buffer circuits 62 and 62a as well as voltage generation circuits 60 and 60a for supplying voltages to input terminals of those buffer circuits 62 and 62a are provided to the second power supply voltage Va2 and the third power supply voltage Va3 being two types of reference voltages for noise cancellation, respectively. The buffer circuit 62a has the same circuit configuration as that of the buffer circuit 62. The voltage generation circuit 60a basically has the same circuit configuration as that of the voltage generation circuit 60, but outputs the reference voltage for the third power supply voltage Va3, which is different from the first voltage outputted from the voltage generation circuit 60.

According to the imaging device of the present modified example, even in the case of applying the different reference voltages (namely, the second power supply voltage Va2 and the third power supply voltage Va3) to the power supply line 22 at the time of pre-resetting and at the time of the feedback operation in the course of noise cancellation, it is possible to suppress a voltage drop attributed to the parasitic capacitance on the wiring to which each of the two types of reference voltages is supplied. Thus, the amount of noise reduction in the course of noise cancellation depending on the column position is improved, thereby suppressing deterioration of an image signal to be read out.

Meanwhile, by applying the second power supply voltage Va2 equal to the reference voltage VFD to the power supply line 22 on each column through the buffer circuit 62, the current flowing from the constant current source 8a to the vertical signal line 18 in the course of noise cancellation will flow to the buffer circuit 62 instead of flowing to the voltage line 72 that transmits the reference voltage. Thus, it is possible to suppress a voltage drop attributed to the previously generated parasitic capacitance on the wiring to supply the reference voltage and to improve the variation in amount of noise reduction in the course of noise cancellation depending on the column position, thereby suppressing deterioration of the image signal to be read out.

### Modified Example 3

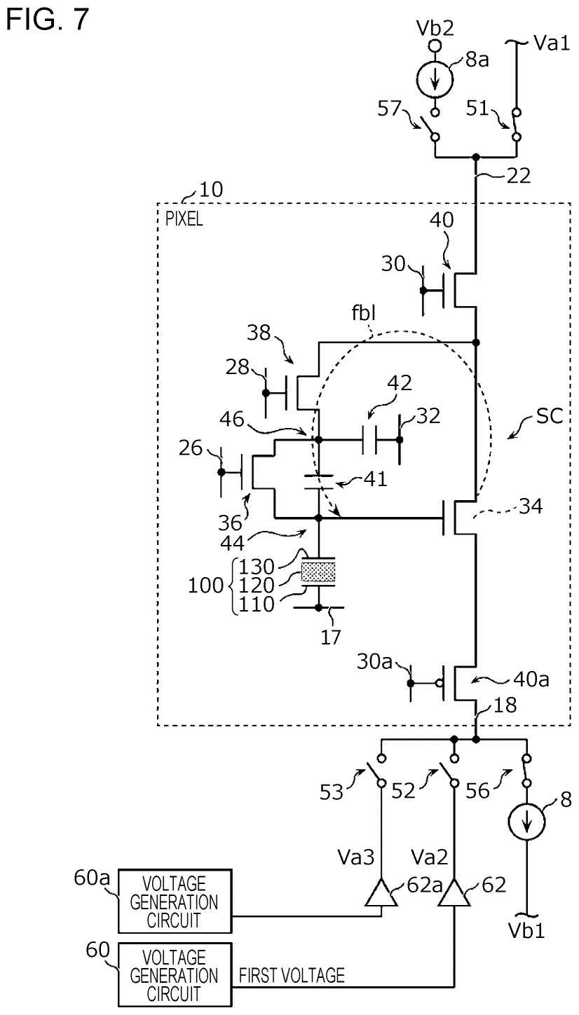

FIG. 7 is a diagram schematically illustrating an exemplary circuit configuration of an imaging device according to Modified Example 3 of the Embodiment 1. In the present modified example, a circuit configuration for readout is different from that of the Modified Example 2. In the present modified example, positions to dispose the constant current source 8 for readout and the switch 56 in the Modified Example 2 switch places with a position to dispose the first switch 51 for supplying the reference voltage for readout (namely, the first power supply voltage Va1) in the Modified Example 2. Moreover, when the address transistor 40 to be connected to one of the source and the drain of the amplification transistor 34 is defined as a first address transistor, a second address transistor 40a to be connected to the other one of the source and the drain of the amplification transistor 34 is additionally provided. A gate of the second address transistor 40a is connected to the vertical scanning circuit 16 through an address signal line 30a.

The constant current source 8a for noise cancellation, the third power supply voltage Va3 being the reference voltage for pre-resetting to be supplied to the first wiring, the second power supply voltage Va2 being the reference voltage for noise cancellation, the switches connected thereto, and the buffer circuits 62 and 62a to be provided to the two types of the reference voltages, respectively, are provided at the same positions of disposition as those in the Modified Example 2.

In the present modified example, the current flows from top down in FIG. 7 at the time of readout, or more specifically, flows sequentially from the first power supply voltage Va1 to the first switch 51, the power supply line 22, the address transistor 40, the amplification transistor 34, the second address transistor 40a, the vertical signal line 18, the switch 56, and the constant current source 8 in a direction opposite to that of the Modified Example 2. The output from the buffer circuits 62 and 62a will be inputted to the vertical signal line 18 instead of the power supply line 22. Accordingly, in the present modified example, the vertical signal line 18 represents an example of the first wiring to which the output voltages from the buffer circuits 62 and 62a are applied.

According to the imaging device of the present modified example, even in the case of applying the reference voltages for noise cancellation (namely, the second power supply voltage Va2 and the third power supply voltage Va3) to the vertical signal line 18, it is possible to suppress a voltage drop attributed to the parasitic capacitance on the wiring that supplies the reference voltages. Thus, the amount of noise reduction depending on the column position is improved, thereby suppressing deterioration of an image signal to be read out.

Meanwhile, by applying the second power supply voltage Va2 equal to the reference voltage VFD to the vertical signal line 18 on each column through the buffer circuit 62, the current flowing from the constant current source 8a to the power supply line 22 in the course of noise cancellation will flow to the buffer circuit 62 instead of flowing to the voltage line 72 that transmits the reference voltage. Thus, it is possible to suppress a voltage drop attributed to the previously generated parasitic capacitance on the wiring to supply the reference voltage and to improve the variation in amount of noise reduction in the course of noise cancellation depending on the column position, thereby suppressing deterioration of the image signal to be read out.

### Embodiment 2

In the imaging device 1 of the Embodiment 1, the buffer circuits 62 having the same configuration are disposed on the respective columns as illustrated in FIG. 4, cach of which is disposed between the first wiring (namely, the power supply line 22 or the vertical signal line 18) on each column and the voltage line 72 that transmits the first voltage for generating the second power supply voltage Va2. Thus, the voltage drop attributed to the parasitic capacitance on the wiring to apply the second power supply voltage Va2 is suppressed and the deterioration of the image signal is improved.

Nevertheless, although having the same configuration, the buffer circuits 62 disposed on the respective columns may occasionally bring about a random output offset not depending on the column position which occurs due to production tolerance of semiconductors in general, or an output offset depending on the column position of the pixel array under the influence of a voltage drop attributed to parasitic capacitance of a power supply line or a voltage drop attributed to parasitic capacitance of a ground line. As a consequence, the second power supply voltages Va2 to be applied to the first wiring (namely, the power supply line 22 or the vertical signal line 18) turn out to be voltages Va2_1′, . . . , Va2_n′, . . . , Va2_m′ obtained by adding the output offsets of the respective buffer circuits 62 to an ideal output voltage. This variation in voltage leads to a variation in FD reset potential, thus causing a variation in amount of noise reduction in the course of noise cancellation.

Given the circumstances, in an imaging device 1a of the Embodiment 2, the output terminals 77 of the adjacent buffer circuits 62 having the same configuration are connected to each other in order to reduce a variation in output offset among the buffer circuits 62. FIG. 8 is a diagram schematically illustrating an exemplary circuit configuration of buffer circuits 62 included in the imaging device 1a according to the Embodiment 2. The output terminals 77 of the respective buffer circuits 62 provided on the respective columns of the pixel array are connected to each other. In other words, FIG. 8 illustrates an example of connecting the output of the first amplification circuit to the output of the second amplification circuit.

Now, assuming that the first voltage to be inputted to be inputted to the buffer circuits 62 is VaX, an output offset provided to a buffer circuit 62 on an N-th column (N is an integer greater than or equal to 2) is ΔVn, and a gain of the relevant buffer circuit 62 is A, an output voltage Va2′ of the buffer circuit 62 on an n-th column turns out to be Va2′=A×VaX+ΔVn. For example, assuming that an output voltage of the first column is Va2_1′ and an output voltage of the second column is Va2_2′, an output voltage Va2_12′ when connecting the output terminals 77 of the buffer circuits 62 of the first column and the second column to each other turns out to be Va2_12′=(Va2_1′+Va2_2′)/2=(A×VaX+ΔV1+VaX+ΔV2)/2=A×VaX+(ΔV1+ΔV2)/2. An output voltage Va2_23′ when connecting the output terminal 77 of the buffer circuit 62 of the second column to the output terminal 77 of the buffer circuit 62 of the third column turns out to be Va2_23′=A×VaX+(ΔV2+ΔV3)/2, thus averaging out the output offsets of the buffer circuits 62 that are adjacent to each other. Likewise, an output voltage Va2_123′ when connecting the output terminals 77 of the buffer circuits 62 of the first to third columns to one another turns out to be Va2_123′=AxVa2+(ΔV1+ΔV2+ΔV3)/3. Moreover, an output voltage Va2(LM) when connecting the output terminals 77 of the buffer circuits 62 of the L-th column to the N-th column (L is an integer greater than or equal to 1 and less than N) turns out to be Va2(LM)=A×VaX+(ΔVL+ΔV(L+1)+ . . . +ΔV (N−1)+ΔVN)/(N−L+1). Thus, it is understood that when the output terminals 77 of the buffer circuits 62 are connected to one another, an average value of the output offsets of the connected buffer circuits 62 turs out to be the output offset.

As described above, according to the imaging device la of the present embodiment, the variation in output offset among the buffer circuits 62 are averaged out by connecting the output terminals 77 of the buffer circuits 62 to one another, whereby the uniform voltage Va2′ is applied to the power supply lines 22 as the second power supply voltage Va2 of the respective columns. Thus, an FD reset potential (hereinafter also simply referred to as a “reset potential”) is uniformized and the variation in amount of noise reduction in the course of noise reduction is also suppressed, thereby suppressing deterioration of an image signal.

### Embodiment 3

In the case of a laminated image sensor configured to laminate the photoelectric conversion film 120 on the semiconductor substrate to be provided with the pixels 10, for example, an FD potential before being reset becomes a higher potential than the reset potential as an amount of incident light or exposure time is greater. Accordingly, the buffer circuit is required to attract a high potential of the FD to a lower reset potential as desired. Meanwhile, in the case of the laminated image sensor assumed in the present embodiment, the potential to reset the FD is a potential that is lower than the power supply voltage. For example, in the case of the buffer circuit 62 including the NMOS-based source follower circuit as illustrated in FIG. 4 and in the case where the output terminal 77 of source follower output attracts the FD potential to a predetermined reset potential, the FD is set to a predetermined reset potential by causing the current source transistor 75 to attract the electric charges accumulated in the FD. The current source for the buffer circuit 62 including the source follower circuit is a constant current source, and a rate of attraction of the electric charges depends on a current capability thereof.

Now, in the case where a current value of the current source is defined as Ic[A]and parasitic capacitance of the FD+ the first wiring is defined as Cc[F], convergence time Tc for setting the FD potential at Vs[V]to the desired reset potential Vr[V]can be calculated by Tc=Cc×(Vs−Vr)/Ic[S]. In the case where the time required for resetting the FD given at a timing to drive this imaging device 1b is shorter than the convergence time Tc, the only option is either to reduce the parasitic capacitance Cc or to increase the current Ic of the current source. However, the parasitic capacitance Cc depends on a capacity of the FD determined in the course of pixel design and on a wiring length of the first wiring determined by the size of the pixel array, and it is extremely difficult to change the parasitic capacitance value for the sake of convenience. In addition, an increase in current Ic of the current source brings about an increase in current consumption by the imaging device and an increase in area of a current source transistor, which are not easily available.

Given the circumstances, a buffer circuit according to Embodiment 3 has a configuration in which the buffer circuit 62 according to the Embodiment 1 is additionally provided with a control switch that switches a gate of the current source transistor 75 to any of a bias voltage application mode and a high voltage application mode. FIG. 9 is a diagram schematically illustrating an exemplary circuit configuration of respective buffer circuits 62b included in the imaging device 1b according to the Embodiment 3. Each buffer circuit 62b according to the present embodiment has a configuration in which the buffer circuit 62 according to the Embodiment 1 is additionally provided with a control switch 80 that switches the gate of the current source transistor 75 to any of the bias voltage application mode and the high voltage application mode. This configuration significantly reduces time for attracting the FD to the reset potential.

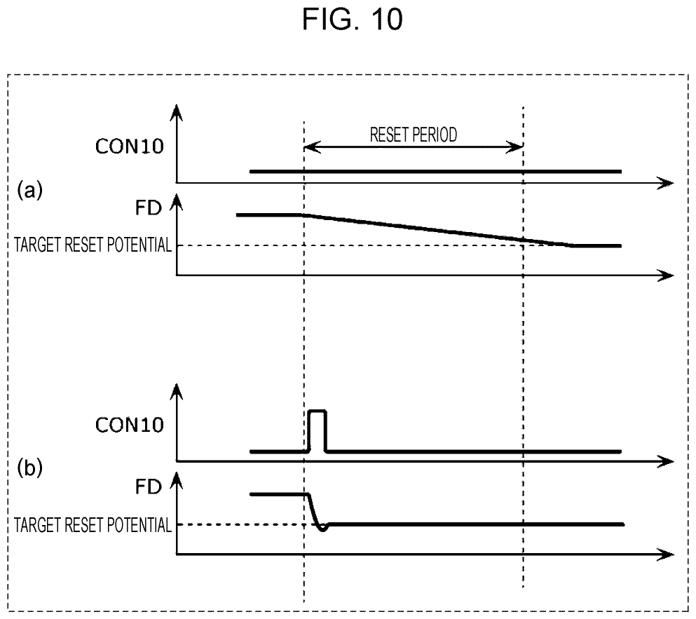

FIG. 10 is a timing chart for explaining an operation of the buffer circuit 62b included in the imaging device 1b according to the Embodiment 3. FIG. 10(a) shows variations of a control signal CON10 to control the control switch 80 and the potential of the FD with time when the gate of the current source transistor 75 is set to the bias voltage application mode, and FIG. 10(b) shows variations of the control signal CON10 to control the control switch 80 and the potential of the FD with time when the gate of the current source transistor 75 is set to the high voltage application mode.

When the current source transistor 75 functions as the current source, the control signal CON10 applies a low level to the control switch 80 in order to establish the bias voltage application mode (“CON10” in FIG. 10(a)). Thus, the control switch 80 is set to a non-conducted state. Accordingly, a bias voltage to be applied from the voltage line 71 is applied to the gate of the current source transistor 75. As a consequence, the current source transistor 75 is operated as the current source and the potential of the FD is gradually reduced from the high potential to a target reset potential (“FD” in FIG. 10(a)).

On the other hand, in the mode of rapidly attracting the potential of the FD, the control signal CON10 applies a high-level pulse to the control switch 80 in order to establish the high voltage application mode only for a short period (“CON10” in FIG. 10(b)). Thus, the control switch 80 is set to a conducted state in a pulse period, and the gate of the current source transistor 75 is connected to a high level potential (the power supply voltage of the voltage line 73 in this case). Accordingly, the current source transistor 75 is turned on in the pulse period and functions as the switch for connecting the output terminal 77 to a low-level potential (such as a ground potential) of the voltage line 70. That is to say, the current source transistor 75 forcibly pulls down the FD and the first wiring (namely, the power supply line 22 or the vertical signal line 18) connected thereto, thereby realizing attraction of the current source transistor 75 which is equal to or more than the current capability when the current source transistor 75 is operated as the current source for the buffer circuit 62b. As a consequence, the potential of the FD suddenly drops from the high potential toward the target reset potential in the pulse period (“FD” in FIG. 10(b)).

According to the imaging device 1b of the present embodiment, the buffer circuit 62b can rapidly attract the potential of the FD to the target reset potential.

In the buffer circuits 62b illustrated in FIG. 9, cach buffer circuit 62b is provided with the control switch 80. Instead, a single control switch 80 may be provided and shared by two or more buffer circuits. For example, one of the two control switches 80 in FIG. 9 need not be provided.

### Modified Example 1

FIG. 11A is a diagram schematically illustrating an exemplary circuit configuration of buffer circuits 62c according to Modified Example 1 of the Embodiment 3. The present modified example is different from the Embodiment 3 in that a control switch 80a connected between the output terminal 77 and the voltage line 70 to supply the ground voltage is provided instead of the control switch 80 in the Embodiment 3. As in the present modified example, the configuration to cause the control switch 80a to directly pull down the output terminal 77 without using the current source transistor 75 can also obtain the same effects as those of the Embodiment 3.

In the present modified example, the control switch 80a is connected between the output terminal 77 and the voltage line 70. Instead, as illustrated in FIG. 11B, the control switch 80a may be connected between the output terminal 77 and another voltage line 70a that represents an example of a fourth voltage line to which a fourth potential is applied. FIG. 11B is a diagram schematically illustrating an exemplary circuit configuration of buffer circuits 62c according to a modification of the Modified Example 1 of the Embodiment 3. For example, a targeted reset potential is applied as a fourth voltage to the voltage line 70a. This configuration can also rapidly attract the potential of the FD to the fourth potential being the target reset potential as with the Modified example 1.

Meanwhile, in the Embodiment 3 and Modified Example 1 thereof, cach buffer circuit is provided with the function to pull down the potential of the FD. Instead, cach buffer circuit may be provided with a function to pull up the potential in the case where potential needs to be attracted to a high level as the target reset potential. To be more precise, the control switch 80 illustrated in FIG. 9 may be connected between the gate of the amplification transistor 76 and the voltage line 70 instead of the connection illustrated in FIG. 9. In this case, the functions of the current source transistor 75 and the amplification transistor 76 are swapped, and these elements will function as the amplification transistor and as the current source transistor, respectively. Here, each of the current source transistor 75 and the amplification transistor 76 is preferably a PMOS transistor.

In the meantime, the control switch 80a illustrated in FIG. 11A may be connected between the voltage line 73 and the output terminal 77 instead of the connection illustrated in FIG. 11A. Thus, each buffer circuit is equipped with a pull-up function, and is capable of rapidly attracting the potential of the FD to a targeted high level.

### Embodiment 4

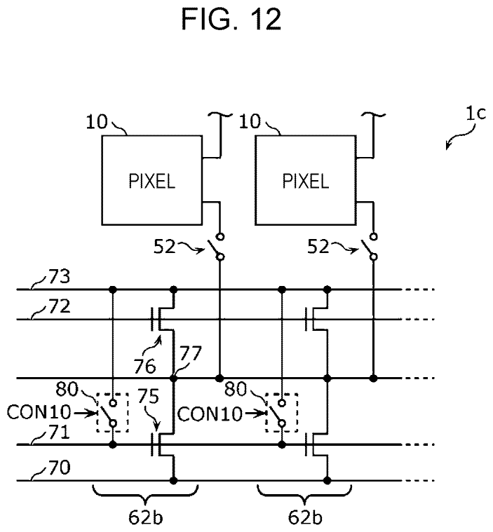

FIG. 12 is a diagram schematically illustrating an exemplary circuit configuration of the buffer circuits 62b included in an imaging device 1c according to Embodiment 4. The present embodiment is equivalent to a combination of the features of the Embodiment 2 and the features of the Embodiment 3. That is to say, in the imaging device lc according to the present embodiment, the output terminals 77 of the buffer circuits 62b provided to each column of the pixel array are connected to each other as with the Embodiment 2. Moreover, each buffer circuit 62b is provided with the control switch 80 as with the Embodiment 3.

According to the imaging device 1c of the present embodiment, the FD reset potentials of the respective columns are uniformized and the potential of the FD can be rapidly attracted to the target reset potential.

Here, in the present embodiment, each buffer circuit 62b may be replaced with the buffer circuit 62c according to the Modified Example 1 of the Embodiment 3. That is to say, the buffer circuit 62c provided with the control switch 80a connected between the output terminal 77 and the voltage line 70 for supplying the ground voltage may be adopted as the buffer circuit in order to rapidly attract the potential of the FD to the target reset voltage.

As described above, according to the imaging devices of the Embodiments 1 to 4 and the modified examples thereof, the buffer circuit to supply the second power supply voltage Va2 and the like for the FD resetting is provided to the first wiring that is connected to the source or the drain of the amplification transistor of the pixel, so that a deviation of the reference voltages between the central column and the peripheral column of the pixel array can be suppressed irrespective of a reference signal, wiring parasitic capacitance on power supply wiring for the buffer circuit, and the like. As a consequence, it is possible to suppress a variation in amount of reduction of reset noise within the pixels depending on the columns, and to obtain an image signal with favorable image quality performances.

### Embodiment 5

The Embodiments 1 to 4 and the modified examples thereof have described the examples in which the techniques of the present disclosure are applied to the voltage supply circuit to supply the reference voltage at the time of the negative feedback operation. However, the present disclosure is not limited to the voltage supply circuit to supply the reference voltage at the time of the negative feedback operation. The present embodiment will describe an example of applying the techniques of the present disclosure to a voltage supply circuit for supplying a reset voltage for resetting the FD. Configurations that are the same as those of the Embodiment 1 will be denoted by the same reference signs as those in the Embodiment 1, and detailed explanations thereof will be omitted.

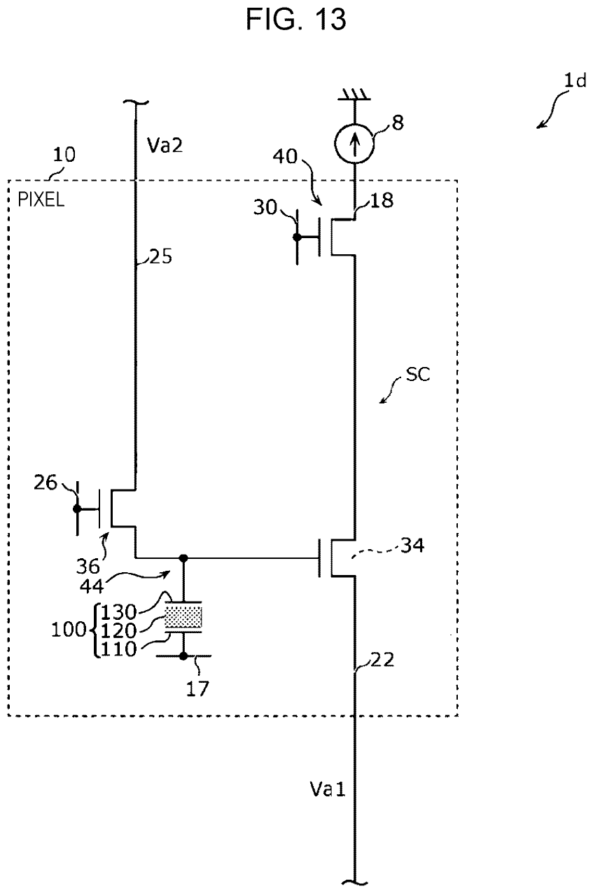

FIG. 13 is a diagram illustrating an exemplary circuit configuration of a pixel 10 in an imaging device Id according to Embodiment 5. The pixel 10 includes the photoelectric converter 100 that subjects incident light to photoelectric conversion, and the signal detection circuit SC that detects a signal generated by the photoelectric converter 100.

The signal detection circuit SC provided to the pixel 10 includes the amplification transistor 34 and the reset transistor 36. Unlike the Embodiment 1, the signal detection circuit SC does not include the feedback loop fb1.

In the configuration exemplified in FIG. 13, the gate of the reset transistor 36 is connected to the reset signal line 26. Meanwhile, one of the source and the drain of the reset transistor 36 as well as the gate of the amplification transistor 34 are connected to the electric charge accumulation region 44. In other words, these electrodes have electrical connection to the pixel electrode 130. The other one of the source and the drain of the reset transistor 36 is connected to a reset voltage line 25 for supplying a reset voltage Va2. One of the source and the drain of the amplification transistor 34 is connected to the power supply line 22. The other one of the source and the drain of the amplification transistor 34 is connected to the vertical signal line 18, which is the signal line to transmit the electric signal outputted from the amplification transistor 34. A power supply voltage Va for readout is applied to the power supply line 22. The electric charge accumulation region 44 is reset by turning the reset transistor 36 on, whereby the voltage of the electric charge accumulation region 44 is set to the reset voltage, namely, the reference voltage.

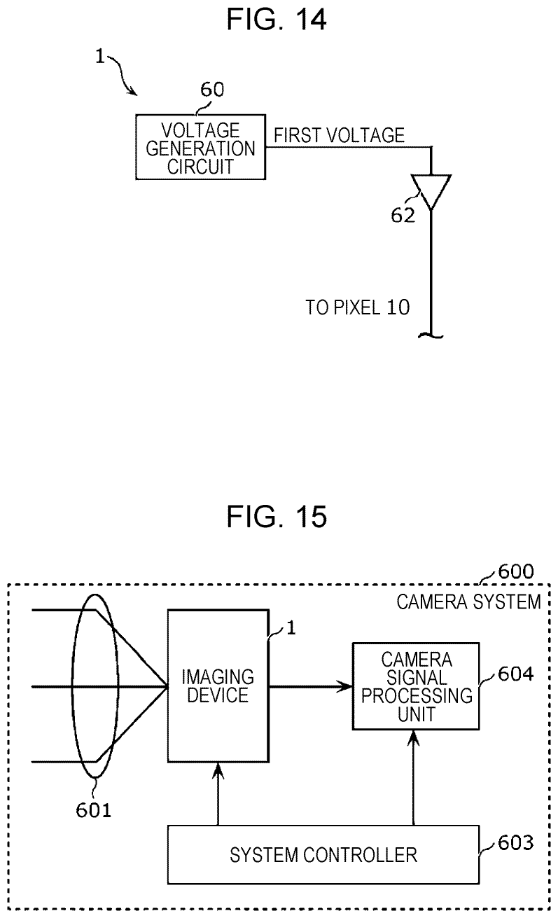

FIG. 14 is a block diagram illustrating a circuit configuration to generate the reset voltage Va2 in FIG. 13. FIG. 14 illustrates the voltage generation circuit 60 that supplies the first voltage being the fixed voltage, and the buffer circuit 62 that amplifies the first voltage supplied from the voltage generation circuit 60 and outputs the amplified voltage as the reset voltage Va2 to the reset voltage line 25. The buffer circuit 62 is the example of the first amplification circuit that amplifies the first voltage, and is the impedance converter with the voltage gain of 1. The voltage generation circuit 60 may be included in the imaging device Id or provided outside of the imaging device 1d. In the case where the voltage generation circuit 60 is provided outside of the imaging device 1d, the first voltage outputted from the voltage generation circuit 60 is supplied to the buffer circuit 62 through the wiring, the connection terminal, and the like.

The circuit configuration to generate the reset voltage Va2 is the same as the configurations described in conjunction with the Embodiments 1 to 4 and the modified examples thereof, and explanations of this circuit configuration will therefore be omitted.

According to the above-described configuration, the reset voltage Va2 equal to the reference voltage VFD is applied through the buffer circuit 62 to the reset voltage line 25 disposed on each column, for example. As a consequence, the current flowing in the course of a resetting operation will flow to the buffer circuit 62 without flowing to the voltage line 72 that transmits the first voltage. Thus, the previously generated voltage drop attributed to the parasitic capacitance on the wiring to supply the reference voltage can be suppressed. Meanwhile, a variation in potential at the time of resetting the electric charge accumulation regions 44 of the respective pixels is improved, thus suppressing the deterioration of the image signal to be read out.

### Embodiment 6

FIG. 15 is a diagram schematically illustrating a configuration example of a camera system 600 according to Embodiment 6. The camera system 600 according to the Embodiment 6 includes the imaging device according to any one of the above-described embodiments and the modified examples thereof (which will be denoted as the imaging device 1 here as a representative of the respective embodiments). The following description will be mainly focused on different features from those of the respective embodiments and the modified examples thereof, and explanations of the common features will be omitted or simplified.

The camera system 600 includes a lens optical system 601, the imaging device 1, a system controller 603, and a camera signal processing unit 604.

The lens optical system 601 includes an autofocus lens, a zoom lens, and a diaphragm, for example. The lens optical system 601 focuses light onto an imaging plane of the imaging device 1.

The imaging device 1 according to any of the above-described embodiments and the modified examples thereof is used as the imaging device 1. The system controller 603 controls the entire camera system 600. The system controller 603 can be implemented by a microcomputer, for example.

The camera signal processing unit 604 functions as a signal processing circuit that processes an output signal from the imaging device 1. The camera signal processing unit 604 carries out processing such as gamma correction, color interpolation processing, space interpolation processing, and automatic white balance. For example, the camera signal processing unit 604 can be implemented by a digital signal processor (DSP) and the like.

According to the camera system 600 of the present embodiment, it is possible to reduce noise and to obtain a fine image by using the imaging device 1 according to any of the above-described embodiments.

The imaging device according to the present disclosure has been described based on the embodiments and the modified examples. However, the present disclosure is not limited to these embodiments and modified examples. Other modes adopting various modifications that can be thought of by those skilled in the art or constructed by combining certain constituents of the embodiments and the modified examples are also encompassed by the scope of the present disclosure.

For example, in the above-described embodiments, the buffer circuits 62 and the like are formed from the NMOS source follower circuits. Instead, the buffer circuits 62 and the like may be formed from PMOS source followers, NMOS input source-grounded amplifiers, PMOS input source-grounded amplifiers, voltage followers adopting operating amplifiers, and the like.

Meanwhile, the present disclosure is also applicable to an aspect of providing multiple vertical signal lines or first wiring elements to each column. In this case, a first pixel and a second pixel may be located on the same column.

The imaging device according to the present disclosure can be used in a video camera, a digital still camera, a monitoring camera, an in-vehicle camera, and the like as an imaging device with reduced noise.

What is claimed is:

1. An imaging device comprising:
a first pixel and a second pixel each including
a photoelectric converter that converts light into electric charges, and
a first transistor connected to the photoelectric converter;
first wiring that is connected to one of a source and a drain of the first transistor of the first pixel;
second wiring that is different from the first wiring and is connected to one of a source and a drain of the first transistor of the second pixel;
a first voltage line to which a first voltage is applied; and
a first amplification circuit that is connected to the first voltage line, amplifies the first voltage, and outputs the amplified first voltage to the first wiring and the second wiring.

2. The imaging device according to claim 1, wherein the first transistor includes a gate connected to the photoelectric converter, and outputs a signal corresponding to an amount of the electric charges.

3. The imaging device according to claim 1, wherein the other of the source and the drain of the first transistor is connected to the photoelectric converter.

4. The imaging device according to claim 1, wherein
the first amplification circuit includes
a second transistor, and
a third transistor connected in series to the second transistor,
a gate of the second transistor is connected to the first voltage line, and
a first node between the second transistor and the third transistor is connected to the first wiring.

5. The imaging device according to claim 4, further comprising:
a second voltage line to which a second voltage is applied; and
a third voltage line to which a third voltage is applied, wherein
the second transistor and the third transistor are connected in series between the second voltage line and the third voltage line.

6. The imaging device according to claim 4, wherein a voltage for causing the third transistor to function as a current source and a voltage for turning on the third transistor are alternately supplied to a gate of the third transistor.

7. The imaging device according to claim 5, wherein the first amplification circuit includes a switch connected between the second voltage line and a gate of the third transistor.

8. The imaging device according to claim 5, wherein the first amplification circuit includes a switch connected between the third voltage line and the first node.

9. The imaging device according to claim 5, further comprising:
a fourth voltage line to which a fourth voltage is applied, wherein
the first amplification circuit includes a switch connected between the fourth voltage line and the first node.

10. The imaging device according to claim 1, wherein each of the first pixel and the second pixel includes a second transistor connected between the other of the source and the drain of the first transistor and the photoelectric converter.

11. The imaging device according to claim 1, further comprising:
a voltage generation circuit that supplies the first voltage to the first voltage line.

12. An imaging device comprising:
a first pixel and a second pixel each including
a photoelectric converter that converts light into electric charges, and
a first transistor connected to the photoelectric converter;
first wiring that is connected to one of a source and a drain of the first transistor of the first pixel;
second wiring that is different from the first wiring and is connected to one of a source and a drain of the first transistor of the second pixel;
a first voltage line to which a first voltage is applied;
a first amplification circuit that is connected to the first voltage line, amplifies the first voltage, and outputs the amplified first voltage to the first wiring; and
a second amplification circuit that is connected to the first voltage line, amplifies the first voltage, and outputs the amplified first voltage to the second wiring.

13. The imaging device according to claim 12, wherein an output terminal of the first amplification circuit is connected to an output terminal of the second amplification circuit.

14. The imaging device according to claim 12, wherein the first transistor includes a gate connected to the photoelectric converter, and outputs a signal corresponding to an amount of the electric charges.

15. The imaging device according to claim 12, wherein the other of the source and the drain of the first transistor is connected to the photoelectric converter.

16. The imaging device according to claim 12, wherein
the first amplification circuit includes
a second transistor, and
a third transistor connected in series to the second transistor,
a gate of the second transistor is connected to the first voltage line, and
a first node between the second transistor and the third transistor is connected to the first wiring.

17. The imaging device according to claim 16, further comprising:
a second voltage line to which a second voltage is applied; and
a third voltage line to which a third voltage is applied, wherein
the second transistor and the third transistor are connected in series between the second voltage line and the third voltage line.

18. The imaging device according to claim 12, wherein each of the first pixel and the second pixel includes a second transistor connected between the other of the source and the drain of the first transistor and the photoelectric converter.

19. The imaging device according to claim 12, further comprising:
a voltage generation circuit that supplies the first voltage to the first voltage line.
